(19) United States
(12) Patent Application Publication
(10) Pub. No.: US 2026/0271631 A1
(43) Pub. Date: Sep. 10, 2026

(54) EPITAXIAL STRONTIUM TITANATE ON SILICON

(71) Applicant: Psiquantum, Corp., Palo Alto, CA (US)

(72) Inventor: Yong Liang, Niskayuna, NY (US)

(73) Assignee: Psiquantum, Corp., Palo Alto, CA (US)

(21) Appl. No.: 19/657,824

(22) Filed: Apr. 24, 2026

Related U.S. Application Data
(63) Continuation of application No. 18/112,395, filed on Feb. 21, 2023, now Pat. No. 12,648,373.
Application No. 18/112,395 is a continuation of application No. 16/791,914, filed on Feb. 14, 2020, now Pat. No. 11,615,954.
(60) Provisional application No. 62/878,653, filed on Jul. 25, 2019.
(60) Provisional application No. 62/878,678, filed on Jul. 25, 2019.

(51) Int. Cl. H10P 14/20; H10D 64/01; H10P 14/24; H10P 14/60; H10P 14/692

(52) U.S. Cl. CPC H10P 14/2905; H10D 64/01342; H10P 14/24; H10P 14/6308; H10P 14/6936

(57) ABSTRACT

A substrate structure includes a silicon-based wafer having a surface and a transition layer disposed on the surface of the silicon-based wafer. The silicon-based wafer can be a single crystal silicon wafer. The transition layer includes silicon oxide. The substrate structure also includes a crystalline strontium titanate layer disposed on the transition layer. The transition layer can also include amorphous silicon-germanium oxide regions or regions of strontium silicon oxide or strontium germanium oxide, for example, amorphous strontium germanium oxide.

### CROSS-REFERENCES TO OTHER APPLICATIONS

This application is a continuation of U.S. Patent Application No. 18/112,395, filed on February 21, 2023, which is a continuation of U.S. Patent Application No. 16/791,914, filed on February 14, 2020, now U.S. Patent No. 11,615,954, issued on March 28, 2023, which claims priority to U.S. Provisional Patent Application No. 62/878,678, filed on July 25, 2019, and to U.S. Provisional Patent Application No. 62/878,653, filed on July 25, 2019, which are hereby incorporated by reference in their entirety for all purposes. This application is related to commonly assigned U.S. Patent Application No. 16/791,948, filed on February 14, 2020, now U.S. Patent No. 11,302,528, the disclosure of which is hereby incorporated by reference in its entirety for all purposes.

### FIELD

The described embodiments relate generally to silicon-based wafers for photonic circuits. More particularly, the present embodiments relate to silicon wafers that include an epitaxial layer of SrTiO₃.

### BACKGROUND

Currently there are several methods available for forming an epitaxial layer of SrTiO₃ on a silicon wafer. Some methods use a “pulsed” process in which the wafer is subjected to a high oxygen atmosphere for a brief period while the SrTiO₃ layer is deposited. Each pulse is followed by an exposure to high temperature to crystallize the SrTiO₃ layer and a lengthy cooling cycle before the subsequent deposition pulse. Care must be taken to minimize the exposure of the wafer simultaneously to a high oxygen pressure and to high temperatures so the surface of the silicon does not form SiO₂. Thus, in this process the only time when the SrTiO₃ layer can be grown is during the brief deposition pulse, whereas during the lengthy cooling cycle no growth takes place, limiting the throughput of the process.

In other embodiments, the oxygen pressure within the chamber is maintained relatively low while the temperature is held relatively high to increase the growth rate of crystalline SrTiO₃. However, because of the high temperature the process can difficult to control so SiO₂ is not formed on the silicon surface and further, the growth rate of SrTiO₃ remains a process bottleneck. In addition, both of the processes described above form the SrTiO₃ layer directly on the silicon, which has a relatively poor lattice match to SrTiO₃, resulting in reduced quality of the SrTiO₃ layer and a strained interface.

New methods for forming an epitaxial SrTiO₃ layer on a silicon wafer are needed that result in increased growth rate, wider process controls and an improved lattice match to the silicon.

### SUMMARY

In some embodiments method for processing a substrate comprises positioning the substrate in a deposition chamber, wherein the substrate comprises a wafer of single crystal silicon. One or more intermediate layers are formed on the wafer of silicon and an amorphous strontium titanium oxide layer is formed on the one or more intermediate layers. The amorphous strontium titanium oxide layer is converted to a crystalline strontium titanium oxide layer and the one or more intermediate layers are oxidized. A thickness of the crystalline strontium titanium oxide layer is increased.

In some embodiments the crystalline strontium titanium oxide layer comprises crystalline strontium titanate. In various embodiments the amorphous strontium titanium oxide layer is formed in an environment in which oxygen pressure is reduced while temperature is simultaneously increased. In some embodiments the one or more intermediate layers comprise germanium. In various embodiments the one or more intermediate layers comprise a combination of strontium and silicon.

In some embodiments the one or more intermediate layers comprise a combination of strontium, germanium and silicon. In various embodiments the one or more intermediate layers comprise a graded layer that transitions from a composition greater in silicon than germanium at the wafer of silicon to a composition greater in germanium than silicon at a top surface of the one or more intermediate layers. In some embodiments oxidizing the one or more intermediate layers creates a transition layer comprising Si1-xGexO2 and SrSiO.

In some embodiments a method for forming a crystalline strontium titanium oxide layer on a silicon-based substrate comprises depositing a strontium containing layer on the silicon-based substrate and depositing an amorphous strontium titanium oxide layer on the strontium containing layer. The amorphous strontium titanium oxide layer is converted to the crystalline strontium titanium oxide layer. The strontium containing layer is oxidized and a thickness of the crystalline strontium titanium oxide layer is increased. In various embodimetns the amorphous strontium titanium oxide layer is deposited in an environment in which oxygen pressure is reduced while temperature is simultaneously increased.

In some embodiments a silicon germanium layer is deposited on the silicon-based substrate before the depositing the strontium containing layer. In various embodiments the silicon germanium layer is a graded layer that transitions from a composition greater in silicon than germanium at the silicon substrate to a composition greater in germanium than silicon at a top surface of the graded layer. In some embodiments the crystalline strontium titanium oxide layer comprises crystalline strontium titanate. In various embodiments a layer of strontium silicide is formed when depositing the strontium containing layer on the silicon-based substrate. In some embodiments oxidizing the strontium containing layer creates a transition layer comprising Si1-xGexO2 and SrSiO.

In some embodiments a method for processing a substrate comprises positioning the substrate in a deposition chamber, wherein the substrate comprises a top layer of silicon. One or more transition layers are formed on the top layer of silicon. An amorphous layer of strontium titanium dioxide is formed on the one or more transition layers. The substrate is heated to a temperature above 500 °C causing the amorphous layer of strontium titanium dioxide to convert to a crystalline layer of strontium titanium dioxide. In various embodiments the amorphous layer of strontium titanium dioxide is formed in an environment in which oxygen pressure is reduced while temperature is simultaneously increased.

In some embodiments the one or more transition layers comprise strontium. In various embodiments the one or more intermediate layers comprise germanium. In some embodiments the one or more intermediate layers comprise a combination of strontium and silicon.

To better understand the nature and advantages of the present disclosure, reference should be made to the following description and the accompanying figures. It is to be understood, however, that each of the figures is provided for the purpose of illustration only and is not intended as a definition of the limits of the scope of the present disclosure. Also, as a general rule, and unless it is evident to the contrary from the description, where elements in different figures use identical reference numbers, the elements are generally either identical or at least similar in function or purpose.

### BRIEF DESCRIPTION OF THE DRAWINGS

FIGS. 1A-1F illustrate simplified cross-sectional views of steps for forming a crystalline SrTiO₃ layer on a silicon wafer, according to embodiments of the disclosure;

FIG. 2 is a method for forming the crystalline SrTiO₃ layer on a silicon wafer according to the steps illustrated in FIGS. 1A-1F;

FIGS. 3A-3C illustrates example processing parameters for growing an amorphous SrTiO₃ layer on the silicon wafer described in FIGS. 1A-1F and 2;

FIGS. 4A-4F illustrate simplified cross-sectional views of steps for forming a SrTiO₃ layer on a silicon wafer that includes a graded silicon germanium layer, according to embodiments of the disclosure;

FIG. 5 is a method for forming the crystalline SrTiO₃ layer on a silicon wafer according to the steps illustrated in FIGS. 4A-4F;

FIGS. 6A-6F illustrates simplified cross-sectional views of steps for forming a crystalline SrTiO₃ layer on a silicon wafer that includes a strontium silicon layer, according to embodiments of the disclosure; and

FIG. 7 is a method for forming the crystalline SrTiO₃ layer on a silicon wafer according to the steps illustrated in FIGS. 6A-6F.

### DETAILED DESCRIPTION

Some embodiments of the present disclosure relate to methods for forming an epitaxial layer of SrTiO₃ on a silicon wafer. Some embodiments relate to the formation of an intermediate amorphous Si₁₋ₓGeₓO₂ or SiO₂ layer between the silicon and the SrTiO₃. While the present disclosure can be useful for a wide variety of configurations, some embodiments of the disclosure are particularly useful for forming silicon wafers for use in photonic circuits, as described in more detail below.

For example, in some embodiments a silicon wafer includes atomic deposits of Ge randomly distributed across a top surface. A layer of SrTiO₃ can then be formed on the silicon surface using a process that starts at a high oxygen pressure and a low temperature while a thin amorphous SrTiO₃ film is formed. The pressure can be reduced while simultaneously increasing the temperature, all the while depositing SrTiO₃. As the temperature increases the SrTiO₃ crystallizes as the oxygen pressure is reduced and the temperature continually increases to a steady state. After growing an initial SrTiO₃ layer, the wafer can be exposed to an oxidizing annealing treatment to convert the Ge that was distributed across the top surface of the silicon (now disposed between the Si and the SrTiO₃ layer), to amorphous Si₁₋ₓGeₓO₂ which is transparent to certain wavelengths of laser light. The wafer can then be exposed to an environment of moderate oxygen pressure and high temperature to grow the SrTiO₃ layer to the desired final thickness.

In another example, a silicon wafer includes a graded layer of Si₁₋ₓGeₓ where the graded layer changes concentration from a low concentration of Ge at the Si wafer interface to a higher concentration of Ge at the top of the graded layer. The graded layer can be used to accommodate the lattice mismatch between silicon and the subsequent SrTiO₃ layer. A layer of Sr can be deposited on the graded layer, followed by a layer of SrTiO₃ using the method described above. During an oxidizing annealing treatment, as described above, the graded layer of Si₁₋ₓGeₓ, is converted to Si₁₋ₓGeₓO₂ which is transparent to certain wavelengths of laser light.

In another example, a layer of Sr is deposited on a silicon wafer. A subsequent layer of SrTiO₃ can be deposited on the layer of Sr, using the method described above. During a subsequent oxidizing annealing treatment the surface of the silicon is converted to SiO₂, which is transparent to certain wavelengths of laser light.

In order to better appreciate the features and aspects of forming epitaxial SrTiO₃ layers on silicon wafers according to the present disclosure, further context for the disclosure is provided in the following section by discussing several methods of forming epitaxial SrTiO₃ layers on silicon wafers, according to embodiments of the present disclosure. These embodiments are for example only and other methods can be employed to form epitaxial SrTiO₃ layers on a photonic wafer.

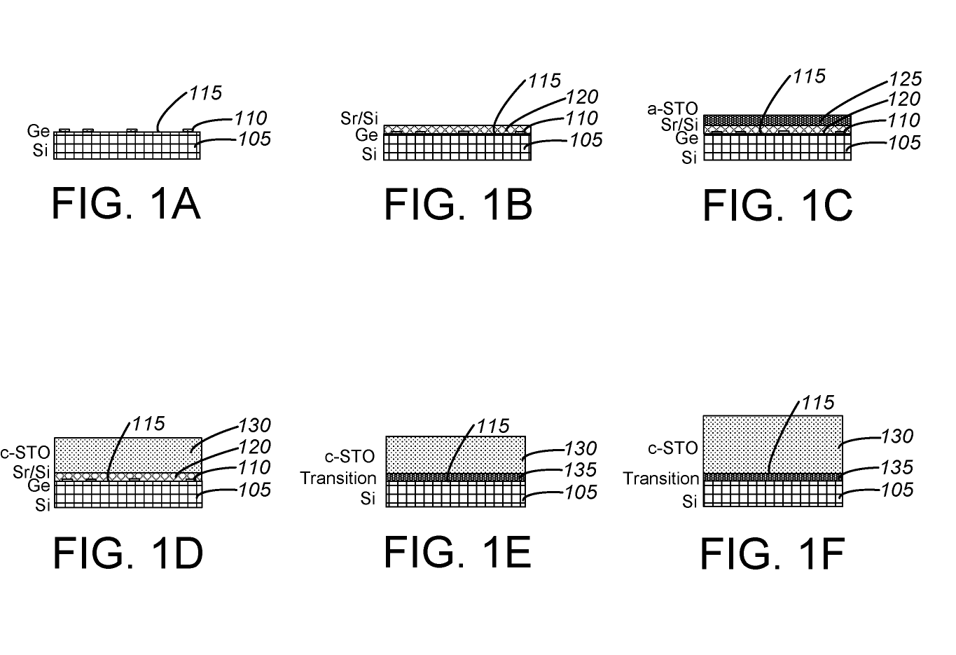

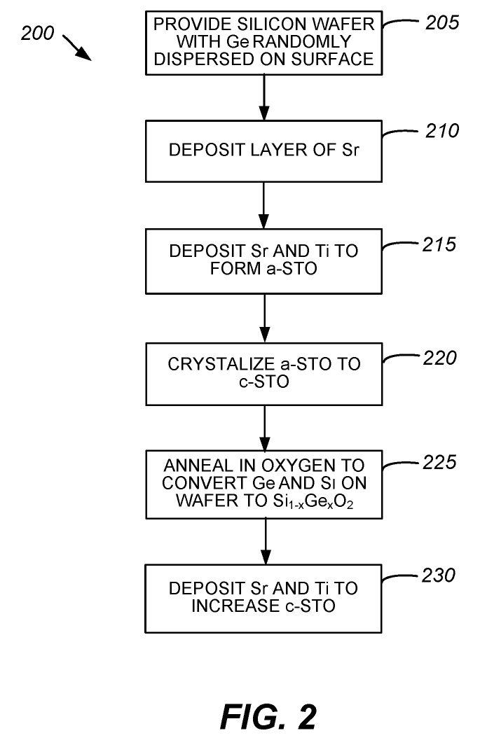

FIGS. 1A-1F illustrate simplified cross-sectional views of steps, according to a method 200 described in FIG. 2, for forming a SrTiO₃ layer on a silicon wafer, according embodiments of the disclosure.

As illustrated in FIG. 1A (step 205 of FIG. 2) a silicon wafer 105 that includes atomic deposits of Germanium (Ge) 110 randomly dispersed on a top surface 115 is provided. In some embodiments silicon wafer 105 can be between 500 microns and 1000 microns thick and can have a single crystal structure. In other embodiments silicon wafer 105 can be in form of silicon on insulator (SOI) where a top layer of thin silicon is separated from the supporting bulk silicon by a layer of insulating SiO₂.

As illustrated in FIG. 1B (step 210 of FIG. 2) strontium (Sr) is deposited on top surface 115 of silicon wafer 105 forming an epitaxial layer of strontium silicide (SrSi) 120. In some embodiments layer of SrSi 120 has a (2x1) structure in which a size of an atomic unit cell is twice as large (2x) as that of the underlying Si in one direction, but is the same size (1x) as that of the of underlying Si in the direction normal to direction that is twice as large as that of the Si. In some embodiments layer of SrSi 120 can be between one half an atomic layer to one atomic layer thick and can be deposited via molecular-beam epitaxy (MBE) or other deposition process.

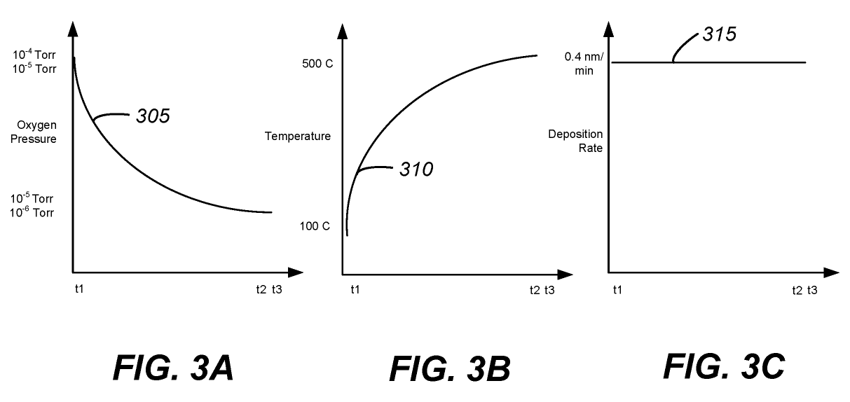

As illustrated in FIG. 1C (step 215 of FIG. 2) a layer of amorphous strontium titanate (SrTiO₃) 125 can be deposited on layer of SrSi 120. Layer of SrSi 120 can be used as a transition layer wherein the Sr is atomically bonded to layer of SrTiO₃125 and the Si is atomically bonded to silicon wafer 105. In some embodiments the growth of amorphous SrTiO₃ layer 125 can be performed in a transient environment, as described in more detail in FIGS. 3A-3C. In some embodiments any composition of strontium titanium oxide can be used for layer 120.

Now referring to FIGS. 3A-3C, example process parameters of one method for growing SrTiO₃ layer 125 are described. As shown in FIG. 3A, at time t1, which is an initiation of the growth of amorphous SrTiO₃ layer 125 (see FIG. 1C), oxygen pressure 305 is held within a range of 10⁻⁴ to 10⁻⁵ torr. As shown in FIG. 3B, at the same time t1, a temperature 310 of the substrate is controlled below 200 °C. Further, as shown in FIG. 1C, at time t1 elemental Sr and Ti are introduced to deposit amorphous SrTiO₃ layer 125 at a substantially constant deposition rate 315. As amorphous SrTiO₃ layer 125 forms it can create a protective barrier to prevent the formation of SiO₂ that can be formed from oxygen penetrating layer of SrSi 120 and oxidizing underlying top surface 115 of silicon wafer 105. In some embodiments a SrTiO₃ layer 125 thickness of 2-10 monolayers can be adequate to protect the top surface 115 of silicon wafer 105 from forming SiO₂, when using process parameters similar to those described in FIGS. 3A-3C. One of skill in the art will appreciate that at lower temperatures a relatively thinner SrTiO₃ layer 125 may be used and at higher temperatures a relatively thicker SrTiO₃ layer may be used.

As further illustrated in FIGS. 3A-3C, as time progresses to t2, the oxygen pressure can be reduced to 10⁻⁵ to 10⁻⁶ torr and the temperature can be increased to approximately 550 °C. During this transition, Sr and Ti are continually introduced to the silicon wafer such that the growth rate of SrTiO₃ layer 125 remains roughly constant, as shown in FIG. 3C. In some embodiments the growth rate of the SrTiO₃ layer 125 is approximately 0.4 nanometers/minute. As would be appreciated by one of skill in the art, this disclosure is not limited to the example process parameters described herein. In other embodiments other oxygen pressures, substrate temperatures and deposition rates can be used without departing from this disclosure. In one example the oxygen pressure can be reduced to between 10⁻⁴ to 10⁻⁷ torr and the temperature can be increased to a range between 500 °C to 600 °C.

As illustrated in FIG. 1D (step 220 of FIG. 2), as the temperature of silicon wafer 105 increases (see t2 in FIG. 3B), amorphous SrTiO₃ layer 125 (see FIG. 1C) crystalizes, forming an epitaxial crystalline SrTiO₃ layer 130. As shown in FIG. 3C, the growth rate of SrTiO₃ layer 130 remains substantially constant from t1 to t2. Because SrTiO₃ layer 130 is now crystalline, the new SrTiO₃ layer grown on crystallized SrTiO₃ is also crystalline.

In one embodiment, as SrTiO₃ layer 130 approaches a thickness of approximately 3 nanometers, the oxygen pressure and the temperature can be stabilized (see t3 in FIGS. 3A, 3B) and crystalline SrTiO₃ layer 130 continues to grow at a substantially constant growth rate. In some embodiments, at a thickness of approximately 3 nanometers, SrTiO₃ layer 130 is of sufficient thickness to stabelize the SrTiO₃ layer and to prevent oxidation of the underlying Si due to diffusion of oxygen through the SrTiO₃ layer 130, thus the oxygen partial pressure can be increased, if desired, during the remainder of the SrTiO₃ layer growth. Additionally, in some embodiments the growth rate of SrTiO₃ layer 130 can be increased by increasing the Sr and Ti fluxes during SrTiO₃ layer growth.

As would be appreciated by one of skill in the art with the benefit of this disclosure the thickness of SrTiO₃ layer 130 that is adequate to prevent oxidation of silicon wafer 105 can vary depending upon a temperature of silicon wafer 105, the partial pressure of the oxygen in the growth environment and other factors. Thus, in some embodiments a SrTiO₃ layer 130 thickness that is adequate to prevent oxidation of silicon wafer 105 can be between 1 and 6 nanometers and in various embodiments between 2 and 4 nanometers and in one embodiment between 2.5 and 3.5 nanometers.

As illustrated in FIG. 1E (step 225 of FIG. 2) silicon wafer 105 is exposed to molecular oxygen, atomic oxygen, or ozone at a temperature above 600 °C. The oxygen permeates crystalline SrTiO₃ layer 130 and oxidizes atomic deposits of Ge 110 (see FIG. 1D) and layer of SrSi 120 forming transition layer 135. More specifically, the molecular oxygen converts atomic deposits of Ge 110 to amorphous Si₁₋ₓGeₓO₂ (SiGeO) regions that can be non-uniformly distributed both horizontally across top surface 115 of silicon wafer 105 and vertically, based on the location and concentration of the atomic deposits of Ge 110. The composition of the amorphous Si₁₋ₓGeₓO₂ regions can also vary due to inter-diffusion of the Si₁₋ₓGeₓO₂ with silicon wafer 105. The resulting amorphous Si₁₋ₓGeₓO₂ regions are transparent at certain wavelengths that may be suitable for use in lasers, including 1550 nanometers. The molecular oxygen also converts layer of SrSi 120 to SrSiO and/or Sr(Si,Ge)O. Thus, transition layer 135 can be composed of varying concentrations of amorphous Si₁₋ₓGeₓO₂,SrSiOₓ and/or Sr(Si,Ge)O. Further, during this step, the exposure to annealing temperatures can improve the crystallinity of the crystalline SrTiO₃ layer 130. In some embodiments any composition of silicon germanium oxide can be used in transition layer 135.

As illustrated in FIG. 1F (step 230 of FIG. 2) after the oxidation/annealing step (step 225 of FIG. 2), the crystalline SrTiO₃ layer 130 growth process is restarted and the crystalline SrTiO₃ layer can be grown to the desired thickness. In some embodiments the oxidation/annealing step 225 can be repeated as needed to improve the crystallinity of the crystalline SrTiO₃ layer. In some embodiments step 225 can be repeated, but without exposing the substrate to molecular oxygen.

In some embodiments a ferroelectric oxide such as, but not limited to, BaTiO₃, (Ba,Sr)TiO₃ (BST), (Pb(Zr,Ti)O₃ (PZT), (Pb, La)(Zr,Ti)O₃ (PLZT), (Sr,Ba)Nb₂O₆ (SBN) or LiNbO₃ can be grown on crystalline SrTiO₃ layer 130 using myriad deposition techniques, including but not limited to, MBE, chemical vapor deposition (CVD), sputtering deposition, pulsed laser deposition (PLD) or sol gel process. The resulting stack, ferroelectric oxide/SrTiO₃/Si₁₋ₓGeₓO₂/Si can be transparent to certain wavelengths of light, including 1550 nanometers, making the structure useful, for example, for optical switches and waveguides. In yet further embodiments, the aforementioned post oxidation process can be employed after a ferroelectric layer is grown on the SrTiO₃/Si₁₋ₓGeₓO₂/Si stack.

It will be appreciated that process 200 is illustrative and that variations and modifications are possible. Steps described as sequential may be executed in parallel, order of steps may be varied, and steps may be modified, combined, added or omitted.

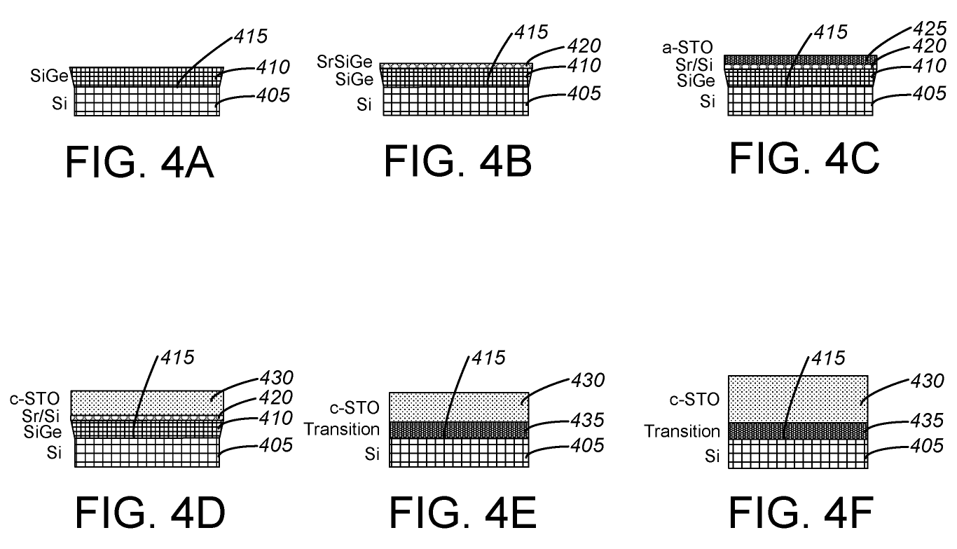

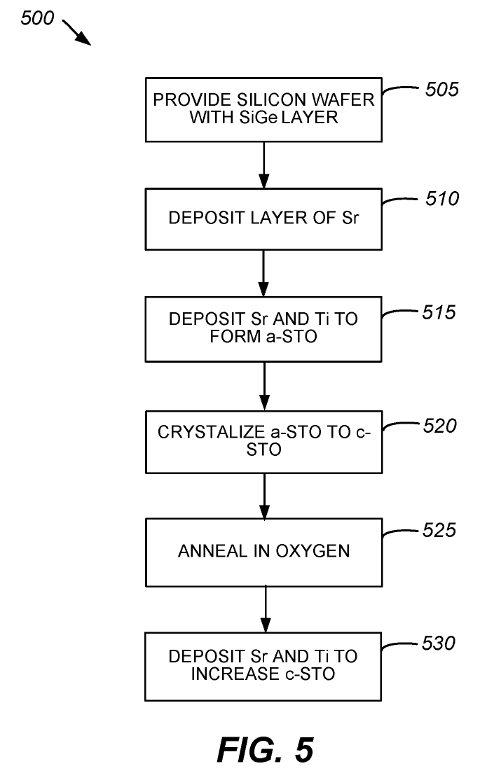

FIGS. 4A-4F illustrate simplified cross-sectional views of steps, according to a method 500 described in FIG. 5, for forming a SrTiO₃ layer on a silicon wafer, according embodiments of the disclosure. As shown in FIG. 5, method 500 uses a similar process as method 200, however in method 500 first step 505 uses a silicon wafer having a SiGe layer, instead of the silicon wafer having randomly distributed Ge atoms. Further, method 500 includes step 510 to oxidize the SiGe layer.

As illustrated in FIG. 4A (step 505 of FIG. 5) a silicon wafer 505 that includes a pregrown epitaxial graded layer of Si₁₋ₓGeₓ410 is provided. In some embodiments a graded layer of Si₁₋ₓGeₓ410 can be deposited. In other embodiments graded layer of Si₁₋ₓGeₓ410 may be pre-deposited on silicon wafer 505 and include a native oxide of Si₁₋ₓGeₓO₂ that may be removed before further processing of the wafer is performed. In various embodiments graded layer of Si₁₋ₓGeₓ410 can change composition through its thickness such that at silicon surface 415 the graded layer of Si₁₋ₓGeₓ has a higher percentage of silicon and has therefore closely matches the lattice of silicon wafer 405 and transitions to a higher percentage of Ge at the top of the layer and therefore closely matches the lattice of the subsequent SrTiO₃ layer (see FIGS. 4D-4F, below). In some embodiments silicon wafer 405 can be a single crystal bulk silicon wafer while in other embodiments silicon wafer 405 can be a SOI wafer where a top thin silicon layer is separated from the supporting bulk silicon by a layer of insulating SiO₂.

As illustrated in FIG. 4B (step 510 of FIG. 5) a layer of epitaxial Sr is deposited on layer of Si₁₋ₓGeₓ410 to form an epitaxial layer of SrSi₁₋ₓGeₓ420. In some embodiments layer of SrSi₁₋ₓGeₓ420 has a (2x1) structure in which the size of the atomic unit cell is twice (2x) as large as that of the underlying Si in one direction, but is the same size (1x) as that of the of underlying Si in the direction normal to direction that is twice as large as that of the Si. In some embodiments layer of SrSi₁₋ₓGeₓ420 can be between one half to one atomic layer thick and can be deposited via MBE, evaporation or other deposition process.

As illustrated in FIG. 4C (step 515 of FIG. 5) a layer of amorphous SrTiO₃425 can be deposited on layer of SrSi₁₋ₓGeₓ 420. In some embodiments the growth of layer of amorphous SrTiO₃425 is performed in a transient environment, as described in more detail in FIGS. 3A-3C and the accompanying description.. In various embodiments layer of amorphous SrTiO₃425 is deposited with a thickness of 2-10 monolayers which can be sufficient to protect silicon surface 415 from oxidation when using the process parameters described in FIGS. 3A-3C.

As illustrated in FIG. 4D (step 220 of FIG. 5), as the wafer temperature increases (see t2 in FIG. 3B), layer of amorphous SrTiO₃425 (see FIG. 4C) crystalizes forming an epitaxial crystalline SrTiO₃ layer 430. As further shown in FIG. 4D, the crystalline SrTiO₃ layer 430 continues to increase in thickness, however now that the SrTiO₃ layer is crystalline, the growth of the layer is also crystalline. As crystalline SrTiO₃ layer 430 approaches a thickness of approximately 3 nanometers, the oxygen pressure and the temperature can be stabilized (see t3 in FIGS. 3A, 3B) and the crystalline SrTiO₃ layer continues to grow at a steady growth rate. As crystalline SrTiO₃ layer 430 continues to increase in thickness it creates improved protection for silicon surface 415 from oxidation so the process parameters can be optimized for growth of the SrTiO₃ layer with less concern for preventing oxidation of the silicon surface.

As would be appreciated by one of skill in the art with the benefit of this disclosure the thickness of crystalline SrTiO₃ layer 430 that is adequate to prevent oxidation of silicon wafer 405 can vary depending upon a temperature of silicon wafer 405, the concentration of the oxygen in the growth environment and other factors. Thus, in some embodiments a SrTiO₃ layer 430 thickness that is adequate to stabelize itself and to prevent oxidation of silicon wafer 405 can be between 1 and 6 nanometers and in various embodiments between 2 and 4 nanometers and in one embodiment between 2.5 and 3.5 nanometers.

As illustrated in FIG. 4E (step 525 of FIG. 5) silicon wafer 405 is exposed to molecular oxygen at a temperature above 600 °C. The molecular oxygen permeates crystalline SrTiO₃ layer 430 and oxidizes Si₁₋ₓGeₓ layer 410 (see FIG. 4D) and layer of SrSi 420 forming transition layer 435. More specifically, the molecular oxygen converts Si₁₋ₓGeₓ to amorphous Si₁₋ₓGeₓO₂. The composition of the amorphous Si₁₋ₓGeₓO₂ can vary due to inter-diffusion of the Si₁₋ₓGeₓO₂ with silicon wafer 405. The resulting amorphous Si₁₋ₓGeₓO₂ regions are transparent at certain wavelengths that may be suitable for use in lasers, including 1550 nanometers. The molecular oxygen also converts layer of SrSi 420 to SrSiO and/or Sr(Si,Ge)O. Thus, transition layer 435 can be composed of varying concentrations of amorphous Si₁₋ₓGeₓO₂,SrSiO and/or Sr(Si,Ge)O. Further, during this step, the exposure to annealing temperatures can improve the crystallinity of crystalline SrTiO₃ layer 430.

As illustrated in FIG. 4F (step 430 of FIG. 5) after oxidation/annealing step 525, crystalline SrTiO₃ layer 430 growth process is restarted and the crystalline SrTiO₃ layer is grown to the desired thickness. In some embodiments oxidation/annealing step 525 can be repeated as needed to improve the crystallinity of crystalline SrTiO₃ layer 430.

It will be appreciated that process 500 is illustrative and that variations and modifications are possible. Steps described as sequential may be executed in parallel, order of steps may be varied, and steps may be modified, combined, added or omitted.

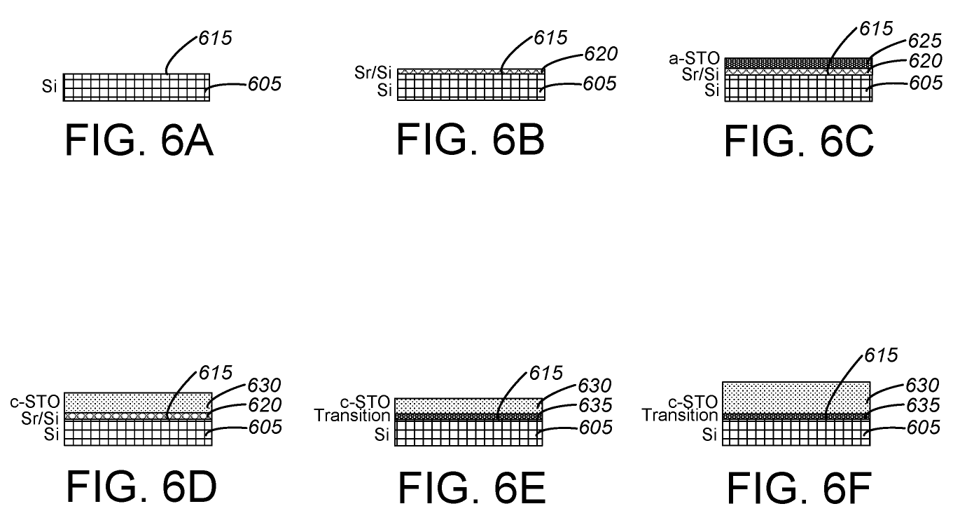

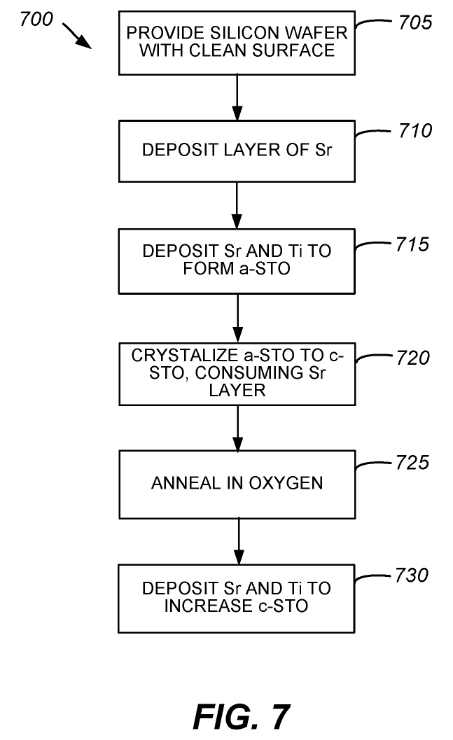

FIGS. 6A-6F illustrate simplified cross-sectional views of steps, according to a method 700 described in FIG. 7, for forming a SrTiO₃ layer on a silicon wafer, according embodiments of the disclosure. As shown in FIG. 7, method 700 uses a similar process as method 200 (see FIGS. 1-3), however in method 700, first step 705 starts with a silicon wafer 605 having no other layers, instead of the silicon wafer with Ge that was used in method 200. Further, method 700 includes step 710 to oxidize a surface of the silicon, as described in more detail below.

As illustrated in FIG. 6A (step 705 of FIG. 7) a single crystal silicon wafer 605 is provided. In some embodiments one or more processes can be performed that remove native oxides from a top surface 615 silicon wafer 605.

As illustrated in FIG. 6B (step 710 of FIG. 7) a layer of Sr is deposited on top surface 615 of silicon wafer 605 to form a layer of SrSi₁₋ₓGeₓ620. In some embodiments layer of SrSi₁₋ₓGeₓ has a (2x1) structure in which the size of the atomic unit cell is twice as large as that of the underlying Si (2x) in one direction, but is the same size as that of the of underlying Si (1x) in the direction normal to direction that is twice as large as that of the Si. In some embodiments the layer of Sr can be between one half an atomic layer to one atomic layer thick and can be deposited via MBE or other deposition process.

As illustrated in FIG. 6C (step 715 of FIG. 7) a layer of amorphous SrTiO₃625 can be deposited on layer of SrSi₁₋ₓGeₓ620. In some embodiments the growth of the layer of SrTiO₃625 is performed in a transient environment, as described in more detail in FIGS. 3A-3C. In some embodiments layer of SrTiO₃625 is deposited to a thickness of 2-10 monolayers, which can sufficient to protect silicon surface 615 from oxidation when using the process parameters described in FIGS. 3A-3C.

As illustrated in FIG. 6D (step 720 of FIG. 7), as a temperature of silicon wafer 605 increases (see t2 in FIG. 3B), layer of amorphous SrTiO₃625 (see FIG. 6C) crystalizes forming an epitaxial crystalline SrTiO₃ layer 630. As further shown in FIG. 6D, crystalline SrTiO₃ layer 630 continues to increase in thickness, however now that the SrTiO₃ layer is crystalline, the growth of the layer is also crystalline. As crystalline SrTiO₃ layer 630 approaches a thickness of approximately 3 nanometers, the oxygen pressure and the temperature can be stabilized (see t3 in FIGS. 3A, 3B) and the crystalline SrTiO₃ layer continues to grow at a steady growth rate. As crystalline SrTiO₃ layer 630 continues to increase in thickness it creates improved protection for silicon surface 615 from oxidation so the process parameters can be optimized for growth of the SrTiO₃ layer with less concern for preventing oxidation of the silicon surface.

As would be appreciated by one of skill in the art with the benefit of this disclosure the thickness of crystalline SrTiO₃ layer 630 that is adequate to prevent oxidation of silicon wafer 605 can vary depending upon a temperature of silicon wafer 605, the concentration of the oxygen in the growth environment and other factors. Thus, in some embodiments a SrTiO₃ layer 630 thickness that is adequate to prevent oxidation of silicon wafer 605 can be between 1 and 6 nanometers and in various embodiments between 2 and 4 nanometers and in one embodiment between 2.5 and 3.5 nanometers.

As illustrated in FIG. 6E (step 725 of FIG. 7) silicon wafer 605 is exposed to molecular oxygen, atomic oxygen, or ozone at a temperature above 600 °C. The oxygen permeates crystalline SrTiO₃ layer 630 and oxidizes layer of SrSi 620 (see FIG. 6D) and top surface 615 of silicon wafer 605, forming transition layer 635. More specifically, the molecular oxygen converts Si to amorphous SiO₂ which is transparent at certain wavelengths that may be suitable for use in lasers, including 1550 nanometers. The molecular oxygen also converts layer of SrSi 620 to SrSiO. Thus, transition layer 635 can be composed of varying concentrations of amorphous SiO₂ andSrSiO. Further, during this step, the exposure to annealing temperatures can improve the crystallinity of crystalline SrTiO₃ layer 630.

As illustrated in FIG. 6F (step 730 of FIG. 7) after oxidation/annealing step 725, crystalline SrTiO₃ layer 630 growth process is restarted and crystalline SrTiO₃ layer 630 is grown to the desired thickness. In some embodiments oxidation/annealing step 725 can be repeated as needed to improve the crystallinity of crystalline SrTiO₃ layer 630.

It will be appreciated that process 700 is illustrative and that variations and modifications are possible. Steps described as sequential may be executed in parallel, order of steps may be varied, and steps may be modified, combined, added or omitted.

In the foregoing specification, embodiments of the disclosure have been described with reference to numerous specific details that can vary from implementation to implementation. The specification and drawings are, accordingly, to be regarded in an illustrative rather than a restrictive sense. The sole and exclusive indicator of the scope of the disclosure, and what is intended by the applicants to be the scope of the disclosure, is the literal and equivalent scope of the set of claims that issue from this application, in the specific form in which such claims issue, including any subsequent correction. The specific details of particular embodiments can be combined in any suitable manner without departing from the spirit and scope of embodiments of the disclosure.

Additionally, spatially relative terms, such as "bottom or "top" and the like can be used to describe an element and/or feature's relationship to another element(s) and/or feature(s) as, for example, illustrated in the figures. It will be understood that the spatially relative terms are intended to encompass different orientations of the device in use and/or operation in addition to the orientation depicted in the figures. For example, if the device in the figures is turned over, elements described as a "bottom" surface can then be oriented "above" other elements or features. The device can be otherwise oriented (e.g., rotated 90 degrees or at other orientations) and the spatially relative descriptors used herein interpreted accordingly.

What is claimed is:

1. A substrate structure comprising:
a silicon-based wafer having a surface;
a transition layer disposed on the surface of the silicon-based wafer, the transition layer comprising silicon oxide; and
a crystalline strontium titanate layer disposed on the transition layer.

2. The substrate structure of claim 1 wherein the silicon-based wafer comprises a wafer of single-crystal silicon.

3. The substrate structure of claim 1 wherein the silicon-based wafer comprises a silicon-on-insulator wafer and the surface comprises a silicon surface separated from bulk silicon by an insulating silicon dioxide layer.

4. The substrate structure of claim 1 wherein the transition layer is disposed directly on the surface of the silicon-based wafer.

5. The substrate structure of claim 1 wherein the crystalline strontium titanate layer is disposed directly on the transition layer.

6. The substrate structure of claim 1 wherein the crystalline strontium titanate layer comprises an epitaxial strontium titanate layer.

7. The substrate structure of claim 1 wherein the crystalline strontium titanate layer has a thickness between 1 nanometer and 6 nanometers.

8. The substrate structure of claim 7 wherein the thickness is between 2.5 nanometers and 3.5 nanometers.

9. The substrate structure of claim 1 further comprising a ferroelectric oxide layer including barium titaniate disposed on the crystalline strontium titanate layer.

10. The substrate structure of claim 1 wherein the transition layer further comprises amorphous silicon-germanium oxide regions.

11. The substrate structure of claim 10 wherein the transition layer further comprises strontium silicon oxide.

12. The substrate structure of claim 10 wherein the transition layer further comprises strontium germanium oxide.

13. The substrate structure of claim 12 wherein the strontium germanium oxide comprises amorphous strontium germanium oxide.

14. The substrate structure of claim 10 wherein the amorphous silicon-germanium oxide regions are non-uniformly distributed across the surface of the silicon-based wafer.

15. The substrate structure of claim 10 wherein the amorphous silicon-germanium oxide regions are transparent at wavelengths of about 1550 nanometers.

16. The substrate structure of claim 1 wherein the silicon-based wafer comprises a single crystal silicon wafer.

17. The substrate structure of claim 16 wherein the transition layer consists of silicon oxide and strontium silicon oxide.

18. The substrate structure of claim 16 wherein the transition layer comprises silicon germanium oxide.

19. The substrate structure of claim 18 wherein the transition layer further comprises strontium silicon oxide and strontium germanium oxide.

20. The substrate structure of claim 16 wherein the transition layer consists of silicon germanium oxide, strontium silicon oxide, and strontium germanium oxide.
